(19) United States
(12) Patent Application Publication
(10) Pub. No.: US 2020/0294609 A1
(43) Pub. Date: Sep. 17, 2020

(54) SEMICONDUCTOR STORAGE DEVICE

(71) Applicants: Kabushiki Kaisha Toshiba, Tokyo (JP); Toshiba Electronic Devices & Storage Corporation, Tokyo (JP)

(72) Inventor: Toshiaki Dozaka, Yokohama Kanagawa (JP)

(21) Appl. No.: 16/543,748

(22) Filed: Aug. 19, 2019

(30) Foreign Application Priority Data
Mar. 14, 2019 (JP) 2019-047705

(51) Int. Cl. G11C 17/16; G11C 17/18; G11C 13/00; G11C 29/02

(52) U.S. Cl. CPC G11C 17/165; G11C 29/027; G11C 13/004; G11C 17/18

(57) ABSTRACT

According to one embodiment, there is provided a semiconductor storage device including a latch circuit, a connection circuit, a first fuse element, and a writing circuit. The latch circuit is arranged across a first current path and a second current path. The connection circuit is arranged across the first current path and the second current path. The first fuse element is arranged in the first current path. The writing circuit is electrically connected to one end of the first fuse element. At least one of the latch circuit and the connection circuit has higher current driving capability with respect to the first current path than current driving capability with respect to the second current path.

### CROSS-REFERENCE TO RELATED APPLICATIONS

This application is based upon and claims the benefit of priority from Japanese Patent Application No. 2019-047705, filed on Mar. 14, 2019; the entire contents of which are incorporated herein by reference.

### FIELD

Embodiments described herein relate generally to a semiconductor storage device.

### BACKGROUND

In a semiconductor storage device including a fuse element, a resistive state of the fuse element varies depending on existence/non-existence of writing of bit information into the fuse element. Here, it is desired to appropriately read the bit information from the fuse element.

### BRIEF DESCRIPTION OF THE DRAWINGS

FIG. 1 is a circuit diagram illustrating a configuration of a semiconductor storage device according to an embodiment;

FIG. 2 is a circuit diagram illustrating a configuration of a semiconductor storage device according to a first modification example of the embodiment;

FIG. 3 is a circuit diagram illustrating a configuration of a semiconductor storage device according to a second modification embodiment of the embodiment;

FIG. 4 is a circuit diagram illustrating a configuration of a semiconductor storage device according to a third modification example of the embodiment;

FIG. 5 is a circuit diagram illustrating a configuration of a semiconductor storage device according to a fourth modification example of the embodiment;

FIG. 6 is a circuit diagram illustrating a configuration of a semiconductor storage device according to a fifth modification example of the embodiment;

FIG. 7 is a circuit diagram illustrating a configuration of a semiconductor storage device according to a sixth modification example of the embodiment;

FIG. 8 is a circuit diagram illustrating a configuration of a semiconductor storage device according to a seventh modification example of the embodiment; and

FIG. 9 is a circuit diagram illustrating a configuration of a semiconductor storage device according to an eighth modification example of the embodiment.

### DETAILED DESCRIPTION

In general, according to one embodiment, there is provided a semiconductor storage device including a latch circuit, a connection circuit, a first fuse element, and a writing circuit. The latch circuit is arranged across a first current path and a second current path. The connection circuit is arranged across the first current path and the second current path. The first fuse element is arranged in the first current path. The writing circuit is electrically connected to one end of the first fuse element. At least one of the latch circuit and the connection circuit has higher current driving capability with respect to the first current path than current driving capability with respect to the second current path.

Exemplary embodiments of a semiconductor storage device will be explained below in detail with reference to the accompanying drawings. The present invention is not limited to the following embodiments.

### Embodiment

A semiconductor storage device according to the embodiment is, for example, a one-time programmable (OTP) memory and includes one or more memory circuits including a fuse element. In the semiconductor storage device, a resistive state of the fuse element varies depending on existence/non-existence of writing of bit information into the fuse element. Here, it is desired to appropriately read the bit information from the fuse element.

For example, in a case where a fusing type (poly-fusing type) fuse element is used, it is possible to make a circuit area of the fuse element small compared to a case where a gate breakdown-type fuse element is used since programming in low voltage is possible and high voltage is not necessary. In this case, in order to read existence/non-existence of writing of bit information into a fuse element, it is considered to provide a current path in which a magnitude relationship of resistance is reversed according to existence/non-existence of writing into the fuse element (second current path) in parallel with a current path including the fuse element that is an object of writing (first current path).

Here, when a resistance element that requires a large circuit area is arranged in the second current path as an element to reverse a magnitude relationship of a resistance value in a current path according to existence/non-existence of writing of bit information, there is a tendency that a circuit area of a semiconductor storage device is increased.

For example, there is a possibility that a circuit area of a semiconductor storage device becomes larger than a circuit area required by a specification of a case where the semiconductor storage device has a single-bit configuration. Also, in a case where a semiconductor storage device includes a storage capacity of a several bits for a purpose of trimming (that is, case of including a plurality of memory circuits), when a resistance element is arranged in a second current path in each memory circuit, there is a possibility that a circuit area of the semiconductor storage device further becomes larger than a circuit area required by a specification. Accordingly, there is a possibility that it becomes difficult to mount a semiconductor storage device (such as OTP memory) in a semiconductor device without a logic region and/or a semiconductor device of a small analog product or the like.

Thus, in the present embodiment, a memory circuit is configured in such a manner that current driving capability with respect to a first current path becomes higher than current driving capability with respect to a second current path in a semiconductor storage device, whereby appropriate reading of bit information from a fuse element is made possible without an arrangement of a resistance element in the second current path.

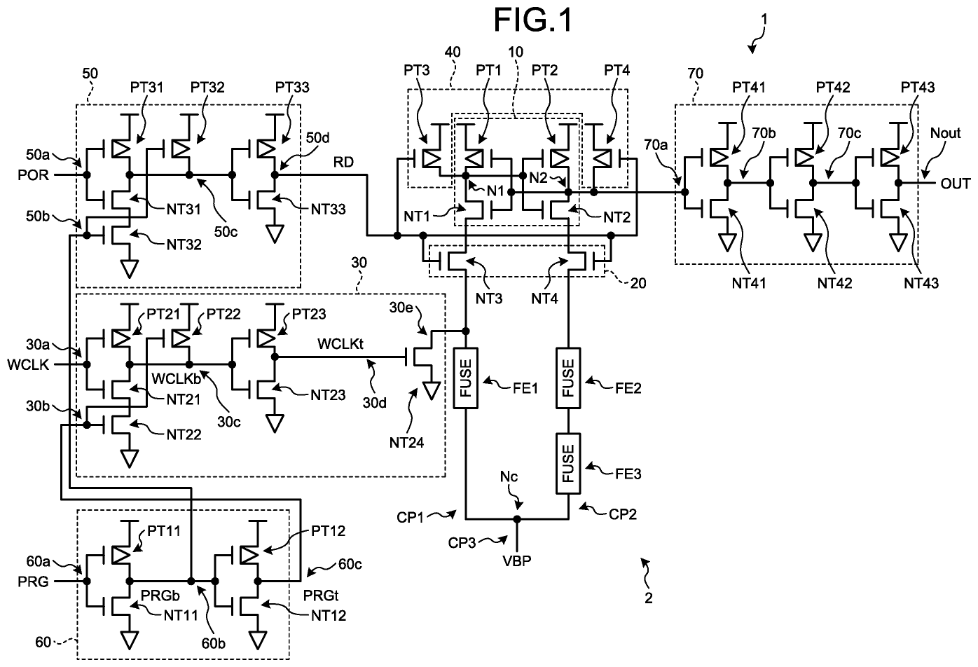

Specifically, a semiconductor storage device 1 may be configured in a manner illustrated in FIG. 1. FIG. 1 is a circuit diagram illustrating a configuration of the semiconductor storage device 1. The semiconductor storage device 1 includes one or more memory circuits 2. Each memory circuit 2 includes a latch circuit 10, a connection circuit 20, a fuse element FE1, a fuse element FE2, a fuse element FE3, a writing circuit 30, a driving circuit 40, a control circuit 50, a signal generating circuit 60, and an output circuit 70.

Two current paths CP1 and CP2 are provided in the memory circuit 2. The current path CP1 and the current path CP2 are current paths from power potential to reference potential VBP through a common current path CP3, and are electrically connected to each other in parallel between the power potential and a common node Nc. The common current path CP3 is electrically connected between the common node Nc and the reference potential VBP.

The latch circuit 10 is placed on a power potential side compared to the connection circuit 20 and the fuse elements FE1 to FE3, and is arranged across the current path CP1 and the current path CP2. The connection circuit 20 is placed between the latch circuit 10 and the fuse elements FE1 to FE3, and is arranged across the current path CP1 and the current path CP2. The fuse element FE1 is placed on a reference potential side compared to the latch circuit 10 and the connection circuit 20, and is arranged in the current path CP1. Each of the fuse elements FE2 and FE3 is placed on the reference potential side compared to the latch circuit 10 and the connection circuit 20, and is arranged in the current path CP2. An input side of the writing circuit 30 is electrically connected to the signal generating circuit 60, and an output side thereof is electrically connected to one end of the fuse element FE1. An input side of the control circuit is electrically connected to the signal generating circuit 60, and an output side thereof is electrically connected to the latch circuit 10 and the connection circuit 20. An input side of the output circuit 70 is electrically connected to the latch circuit 10, and an output side thereof is electrically connected to an output node Nout.

The latch circuit 10 includes an NMOS transistor NT1, a PMOS transistor PT1, an NMOS transistor NT2, and a PMOS transistor PT2.

The NMOS transistor NT1 and the PMOS transistor PT1 are arranged in the current path CP1 and are connected to each other in series in the current path CP1. A gate of each of the NMOS transistor NT1 and the PMOS transistor PT1 is connected to the current path CP2. The NMOS transistor NT2 and the PMOS transistor PT2 are arranged in the current path CP2 and are connected to each other in series in the current path CP2. A gate of each of the NMOS transistor NT2 and the PMOS transistor PT2 is connected to the current path CP1.

A source of the NMOS transistor NT1 is electrically connected to the connection circuit 20, a drain thereof is electrically connected to a node N1, and a gate thereof is electrically connected to a node N2. The node N1 is a node between the MOS transistor NT1 and the PMOS transistor PT1 in the current path CP1. The node N2 is a node between the MOS transistor NT2 and the PMOS transistor PT2 in the current path CP2. A source of a PMOS transistor NT1 is electrically connected to power potential, a drain thereof is electrically connected to the node N1, and a gate thereof is electrically connected to the node N2. A source of the NMOS transistor NT2 is electrically connected to the connection circuit 20, a drain thereof is electrically connected to the node N2, and a gate thereof is electrically connected to the node N1. A source of a PMOS transistor NT2 is electrically connected to the power potential, a drain thereof is electrically connected to the node N2, and a gate thereof is electrically connected to the node N1.

The connection circuit 20 includes an NMOS transistor NT3 and an NMOS transistor NT4.

The NMOS transistor NT3 is electrically connected to the NMOS transistor NT1 and the PMOS transistor PT1 in series in the current path CP1. A source of the NMOS transistor NT3 is electrically connected to the fuse element FE1, a drain thereof is electrically connected to the source of the NMOS transistor NT1, and a gate thereof is electrically connected to the control circuit. The NMOS transistor NT3 receives a control signal from the control circuit at the gate.

The NMOS transistor NT4 is electrically connected to the NMOS transistor NT2 and the PMOS transistor PT2 in series in the current path CP2. A source of the NMOS transistor NT4 is electrically connected to the fuse element FE2, a drain thereof is electrically connected to the source of the NMOS transistor NT2, and a gate thereof is electrically connected to the control circuit. The NMOS transistor NT3 receives a control signal from the control circuit at the gate.

The signal generating circuit 60 includes an NMOS transistor NT11, a PMOS transistor PT11, an NMOS transistor NT12, and a PMOS transistor PT12.

The NMOS transistor NT11 and the PMOS transistor PT11 are connected as an inverter, a common gate being electrically connected to an input node 60a and a common drain being electrically connected to an intermediate node 60b. The NMOS transistor NT12 and the PMOS transistor PT12 are connected as an inverter, a common gate being electrically connected to the intermediate node 60b and a common drain being electrically connected to an output node 60c.

The NMOS transistor NT11 and the PMOS transistor PT11 generate an inverted control signal PRGb that is a control signal PRG inverted logically, and supply the generated signal to the intermediate node 60b and to the control circuit 50 from the intermediate node 60b. The NMOS transistor NT12 and the PMOS transistor PT12 generate a control signal PRGt that is the inverted control signal PRGb further inverted logically, and supply the generated signal from the output node 60c to the writing circuit 30.

The writing circuit 30 includes an NMOS transistor NT21, a PMOS transistor PT21, an NMOS transistor NT22, a PMOS transistor PT22, an NMOS transistor NT23, a PMOS transistor PT23, and an NMOS transistor (writing transistor) NT24.

The NMOS transistor NT21 and the PMOS transistor PT21 are connected as an inverter, a common gate being electrically connected to an input node 30a for a clock signal WCLK and a common drain being electrically connected to an intermediate node 30c. The NMOS transistor NT23 and the PMOS transistor PT23 are connected as an inverter, a common gate being electrically connected to the intermediate node 30c and a common drain being electrically connected to an intermediate node 30d. The NMOS transistor NT22 and the PMOS transistor PT22 are connected in a cascade, a common gate being electrically connected to an input node 30b for the control signal PRGt. A source of the NMOS transistor NT22 is electrically connected to ground potential, and a drain thereof is electrically connected to a source of the NMOS transistor NT21. A source of the PMOS transistor PT22 is electrically connected to the power potential, and a drain thereof is electrically connected to the intermediate node 30c. A gate of the NMOS transistor NT24 (writing transistor) is electrically connected to the intermediate node 30d, a source thereof is electrically connected to the ground potential, and a drain thereof is electrically connected to an output node 30e.

The driving circuit 40 includes a PMOS transistor PT3 and a PMOS transistor PT4. A source of the PMOS transistor PT3 is connected to the power potential, a gate thereof is connected to the control circuit 50, and drain thereof is connected to the node N1. A source of the PMOS transistor PT4 is connected to the power potential, a gate thereof is connected to the control circuit 50, and a drain thereof is connected to the node N2.

The control circuit 50 includes an NMOS transistor NT31, a PMOS transistor PT31, an NMOS transistor NT32, a PMOS transistor PT32, an NMOS transistor NT33, and a PMOS transistor PT33.

The NMOS transistor NT31 and the PMOS transistor PT31 are connected as an inverter, a common gate being electrically connected to an input node 50a for a control signal POR and a common drain being electrically connected to an intermediate node 50c. The NMOS transistor NT33 and the PMOS transistor PT33 are connected as an inverter, a common gate being electrically connected to the intermediate node 50c and a common drain being electrically connected to an output node 50d. The NMOS transistor NT32 and the PMOS transistor PT32 are connected in a cascade, a common gate being electrically connected to an input node 50b for the inverted control signal PRGb. A source of the NMOS transistor NT32 is electrically connected to the ground potential, and a drain thereof is electrically connected to a source of the NMOS transistor NT31. A source of the PMOS transistor PT32 is electrically connected to the power potential, and a drain thereof is electrically connected to the intermediate node 50c.

The output circuit 70 includes an NMOS transistor NT41, a PMOS transistor PT41, an NMOS transistor NT42, a PMOS transistor PT42, an NMOS transistor NT43, and a PMOS transistor PT43.

The NMOS transistor NT41 and the PMOS transistor PT41 are connected as an inverter, a common gate being electrically connected to an input node 70a and a common drain being electrically connected to an intermediate node 70b. The NMOS transistor NT42 and the PMOS transistor PT42 are connected as an inverter, a common gate being electrically connected to the intermediate node 70b and a common drain being electrically connected to an intermediate node 70c. The NMOS transistor NT43 and the PMOS transistor PT43 are connected as an inverter, a common gate being electrically connected to the intermediate node 70c and a common drain being electrically connected to an output node Nout. With this configuration, the output circuit 70 outputs, from the output node Nout, a signal in which bit information read from the fuse element FE1 through the latch circuit 10 is logically inverted.

The memory circuit 2 is configured in such a manner that current driving capability with respect to the current path CP1 becomes higher than current driving capability with respect to the current path CP2.

For example, current driving capability of the NMOS transistor NT1 may be higher than current driving capability of the NMOS transistor NT2 in the latch circuit 10. A dimension (=(gate width)/(gate length)) of the NMOS transistor NT1 is larger than a dimension of the NMOS transistor NT2. A threshold voltage of the NMOS transistor NT1 is lower than a threshold voltage of the NMOS transistor NT2. The NMOS transistor NT1 has a larger dimension than the NMOS transistor NT2 and a lower threshold voltage than the NMOS transistor NT2. Here, current driving capability of the PMOS transistor PT1 may be substantially equal to current driving capability of the PMOS transistor PT2, and current driving capability of the NMOS transistor NT3 may be substantially equal to current driving capability of the NMOS transistor NT4.

Alternatively, current driving capability of the PMOS transistor PT1 may be lower than current driving capability of the PMOS transistor PT2 in the latch circuit 10. A dimension (=(gate width)/(gate length)) of the PMOS transistor PT1 is smaller than a dimension of the PMOS transistor PT2. A threshold voltage of the PMOS transistor PT1 is higher than a threshold voltage of the PMOS transistor PT2. The PMOS transistor PT1 has a smaller dimension than the PMOS transistor PT2 and a higher threshold voltage than the PMOS transistor PT2. Here, current driving capability of the NMOS transistor NT1 may be substantially equal to current driving capability of the NMOS transistor NT2, and current driving capability of the NMOS transistor NT3 may be substantially equal to current driving capability of the NMOS transistor NT4.

Alternatively, current driving capability of the NMOS transistor NT1 may be higher than current driving capability of the NMOS transistor NT2, and current driving capability of the PMOS transistor PT1 may be lower than current driving capability of the PMOS transistor PT2 in the latch circuit 10. Here, current driving capability of the NMOS transistor NT3 may be substantially equal to current driving capability of the NMOS transistor NT4.

Alternatively, current driving capability of the NMOS transistor NT3 may be higher than current driving capability of the NMOS transistor NT4 in the connection circuit 20. A dimension (=(gate width)/(gate length)) of the NMOS transistor NT3 is larger than a dimension of the NMOS transistor NT4. A threshold voltage of the NMOS transistor NT3 is lower than a threshold voltage of the NMOS transistor NT4. The NMOS transistor NT3 has a larger dimension than the NMOS transistor NT4 and a lower threshold voltage than the NMOS transistor NT4. Here, current driving capability of the NMOS transistor NT1 may be substantially equal to current driving capability of the NMOS transistor NT2, and current driving capability of the PMOS transistor PT1 may be substantially equal to current driving capability of the PMOS transistor PT2.

Alternatively, current driving capability of the NMOS transistor NT1 may be higher than current driving capability of the NMOS transistor NT2 in the latch circuit 10, and current driving capability of the NMOS transistor NT3 may be higher than current driving capability of the NMOS transistor NT4 in the connection circuit 20. Here, current driving capability of the PMOS transistor PT1 may be substantially equal to current driving capability of the PMOS transistor PT2.

Alternatively, current driving capability of the PMOS transistor PT1 may be lower than current driving capability of the PMOS transistor PT2 in the latch circuit 10, and current driving capability of the NMOS transistor NT3 may be higher than current driving capability of the NMOS transistor NT4 in the connection circuit 20. Here, current driving capability of the NMOS transistor NT1 may be substantially equal to current driving capability of the NMOS transistor NT2.

Alternatively, current driving capability of the NMOS transistor NT1 may be higher than current driving capability of the NMOS transistor NT2 in the latch circuit 10, current driving capability of the PMOS transistor PT1 may be lower than current driving capability of the PMOS transistor PT2 in the latch circuit 10, and current driving capability of the NMOS transistor NT3 may be higher than current driving capability of the NMOS transistor NT4 in the connection circuit 20.

That is, at least one of the latch circuit 10 and the connection circuit 20 is configured in such a manner that current driving capability with respect to the current path CP1 becomes higher than current driving capability with respect to the current path CP2. Also, a plurality of fuse elements FE2 and FE3 (that is, fuse elements the number of which is larger than that in the current path CP1) is arranged in the current path CP2. Accordingly, it is possible to reverse a magnitude relationship in resistance in the current path CP1 and the current path CP2 equivalently according to existence/non-existence of fusion of the fuse element FE1 (existence/non-existence of writing of bit information) even when no resistance element is arranged in the current path CP2. Note that a layout area of the plurality of fuse elements FE2 and FE3 arranged in the current path CP2 is much smaller than a layout area of a resistance element.

Accordingly, it is possible to make resistance of the current path CP2 higher than resistance of the current path CP1 equivalently according to the fuse element FE1 not being fused (there being no writing of bit information). Also, it is possible to make resistance of the current path CP1 higher than resistance of the current path CP2 equivalently according to the fuse element FE1 being fused (there being writing of bit information). As a result, it is possible to appropriately read bit information from the fuse element FE1.

For example, when the control signal POR becomes an active level (such as H level) and the control signal PRGb becomes an active level (such as H level) before the fuse element FE1 is fused (low resistive state or bit state “0”), a control signal RD becomes an active level (such as H level) and the NMOS transistors NT3 and NT4 of the connection circuit 20 are turned on. Also, since the control signal PRGt logically inverted with respect to the control signal PRGb becomes a non-active level (such as L level), the NMOS transistor NT24 (writing transistor) is kept in an off state.

In a period in which the control signal RD is the active level, current corresponding to a resistance value in a low resistive state of the fuse element FE1 flows in the current path CP1, and current corresponding to a total resistance value of the plurality of fuse elements FE2 and FE3 flows in the current path CP2. Here, since current driving capability with respect to the current path CP1 is higher than current driving capability with respect to the current path CP2 in at least one of the latch circuit 10 and the connection circuit 20 and the plurality of fuse elements FE2 and FE3 is connected to the current path CP2, more current flows in the current path CP1. Accordingly, the output node N2 of the latch circuit 10 holds a state of the “H” level, and the output circuit 70 outputs the “L” level corresponding to the bit state “0” to the output node Nout in response thereto.

When a clock WCLK becomes an active level (such as H level) and the control signal PRGt becomes an active level (such as H level), the NMOS transistor NT24 (writing transistor) is kept in an on state. Also, since the control signal PRGb becomes a non-active level (such as L level), the control signal RD becomes a non-active level (such as L level) and the NMOS transistors NT3 and NT4 of the connection circuit 20 are turned on.

Since the NMOS transistor NT24 (writing transistor) is kept in the on state, a large current flows in the fuse element FE1 due to a potential difference between potential of the node Nc and the ground potential, the fuse element FE1 is fused, and a bit value “1” is stored.

When the control signal POR becomes an active level (such as H level) and the control signal PRGb becomes an active level (such as H level) after the fuse element FE1 is fused (high resistive state or bit state “1”), the control signal RD becomes an active level (such as H level) and the NMOS transistors NT3 and NT4 of the connection circuit 20 are turned on. Also, since the control signal PRGt logically inverted with respect to the control signal PRGb becomes a non-active level (such as L level), the NMOS transistor NT24 (writing transistor) is kept in the off state.

In a period in which the control signal RD is the active level, current corresponding to a total resistance value of the plurality of fuse elements FE2 and FE3 flows in the current path CP2. Here, since the fuse element FE1 is fused, current does not flow in the current path CP1 substantially, and more current flows in the current path CP2. Accordingly, the output node N2 of the latch circuit 10 holds a state of the “L” level, and the output circuit 70 outputs the “H” level corresponding to the bit state “1” to the output node Nout in response thereto.

As described above, in the embodiment, the memory circuit 2 is configured in such a manner that current driving capability with respect to the current path CP1 becomes higher than current driving capability with respect to the current path CP2 in the semiconductor storage device 1. Accordingly, it becomes possible to appropriately read bit information from the fuse element FE1 without arranging a resistance element in the current path CP2. As a result, it is possible to reduce a circuit area of the semiconductor storage device 1, and it becomes possible to implement the semiconductor storage device 1 into a semiconductor device without a logic region and/or a semiconductor device of a small analog product or the like.

Note that when at least one of the latch circuit 10 and the connection circuit 20 is configured in such a manner that current driving capability with respect to the current path CP1 becomes adequately higher than current driving capability with respect to the current path CP2, it is possible to reverse a magnitude relationship of resistance values in the current paths CP1 and CP2 according to existence/non-existence of writing of bit information into the fuse element FE1 even when the number of fuse elements arranged in the current path CP2 is reduced.

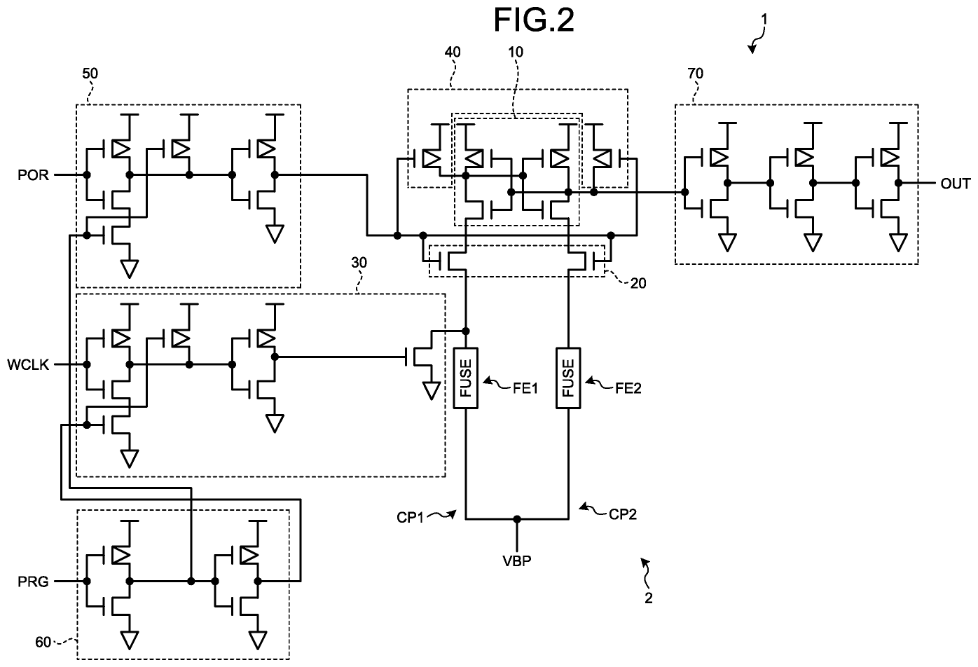

For example, as illustrated in FIG. 2, the number of fuse elements arranged in a current path CP2 may be made identical to the number of fuse elements arranged in a current path CP1 by omission of a fuse element FE3 (see FIG. 1) from the current path CP2. FIG. 2 is a circuit diagram illustrating a configuration of a semiconductor storage device 1 according to a first modification example of the embodiment. In this configuration, it is also possible to realize an effect similar to that of the embodiment and to further reduce a circuit area.

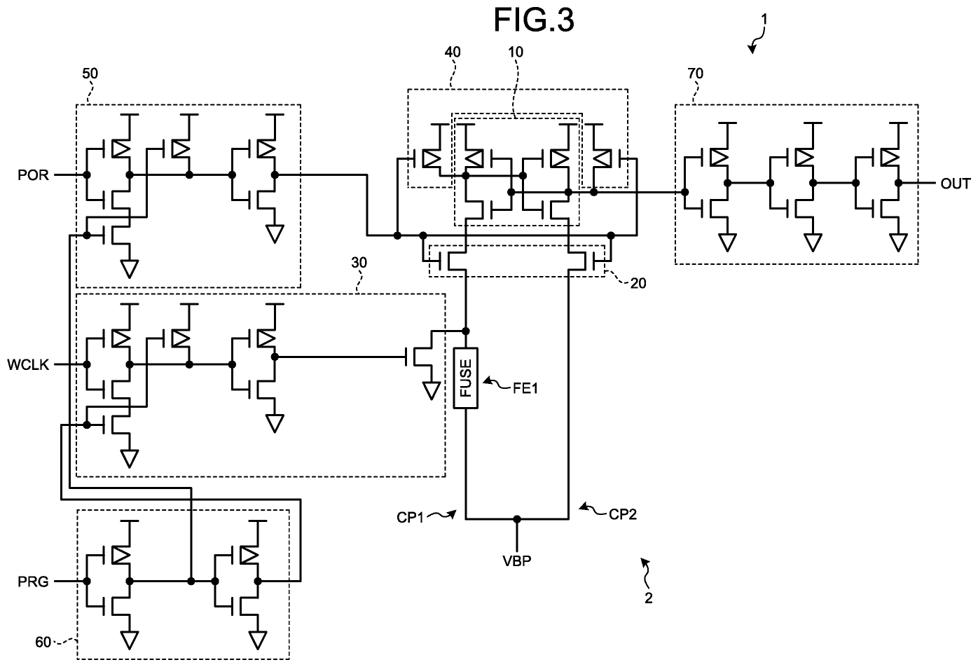

For example, as illustrated in FIG. 3, the number of fuse elements arranged in a current path CP2 may be made smaller than the number of fuse elements arranged in a current path CP1 by omission of fuse elements FE2 and FE3 (see FIG. 1) from the current path CP2. FIG. 3 is a circuit diagram illustrating a configuration of a semiconductor storage device 1 according to a second modification example of the embodiment. In this configuration, it is also possible to realize an effect similar to that of the embodiment and to further reduce a circuit area.

Also, a change in consideration of a balance in a circuit may be added to a semiconductor storage device 1. In a current path CP1, a drain of an NMOS transistor NT24 (writing transistor) is connected between a fuse element FE1 and an NMOS transistor NT3 and it is possible to assume that capacity loads are connected equivalently.

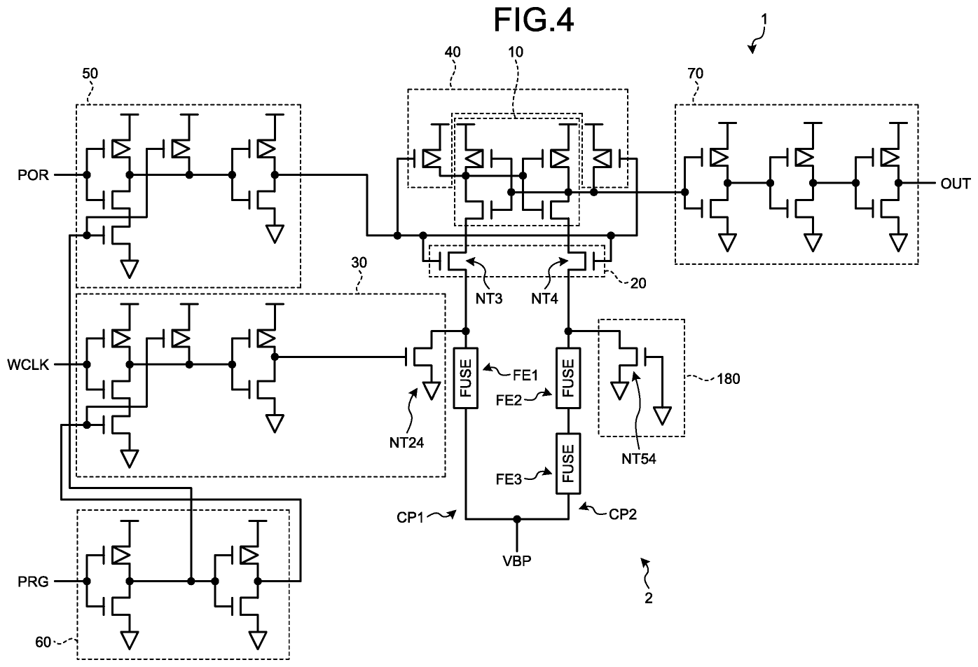

With respect to that, a dummy writing circuit 180 is connected to a current path CP2, for example, as illustrated in FIG. 4. FIG. 4 is a circuit diagram illustrating a configuration of a semiconductor storage device 1 according to a third modification example of the embodiment. The writing circuit 180 is connected to a node between a fuse element FE2 and an NMOS transistor NT4. The writing circuit 180 includes an NMOS transistor NT54. A source of the NMOS transistor NT54 is connected to ground potential, a gate thereof is connected to the ground potential, and a drain thereof is connected to the node between the fuse element FE2 and the NMOS transistor NT4. A dimension (=W/L, W: channel width and L: channel length) of the NMOS transistor NT54 may be substantially equal to a dimension of the NMOS transistor NT24. Accordingly, it is possible not only to realize an effect similar to that of the embodiment but also to make capacity loads the same between the current path CP1 and the current path CP2. As a result, it is possible to increase a margin of a resistance value in a case of reversing a magnitude relationship of resistance values in the current paths CP1 and CP2 according to existence/non-existence of writing of bit information, that is, a bit information reading margin.

Also, in this configuration, when at least one of a latch circuit 10 and a connection circuit 20 is configured in such a manner that current driving capability with respect to the current path CP1 becomes adequately higher than current driving capability with respect to the current path CP2, it is possible to reverse a magnitude relationship of resistance values in the current paths CP1 and CP2 according to existence/non-existence of writing of bit information into the fuse element FE1 even when the number of fuse elements arranged in the current path CP2 is reduced.

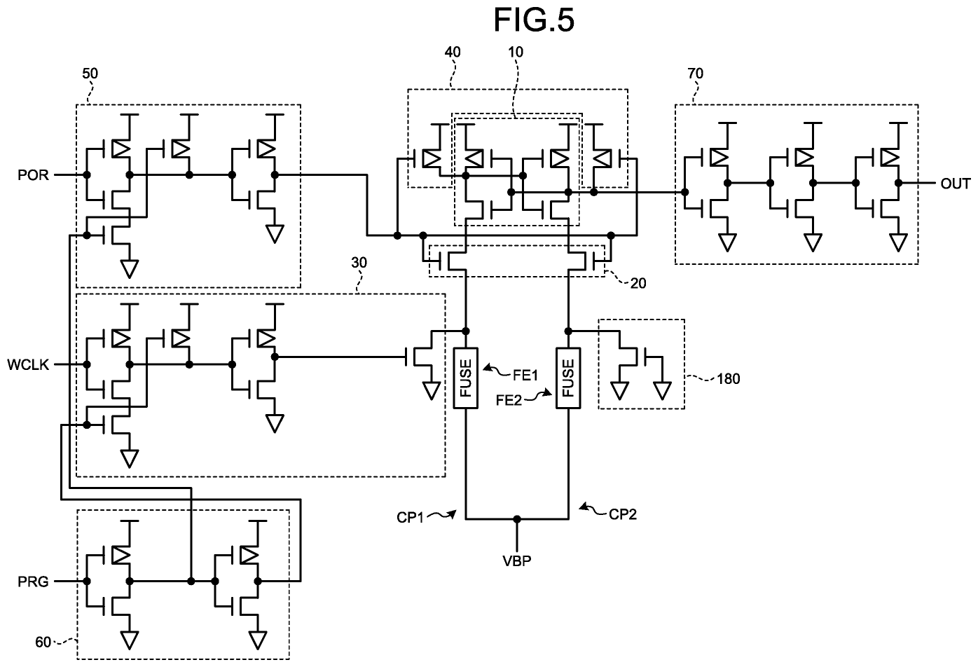

For example, as illustrated in FIG. 5, the number of fuse elements arranged in a current path CP2 may be made identical to the number of fuse elements arranged in a current path CP1 by omission of a fuse element FE3 (see FIG. 4) from the current path CP2. FIG. 5 is a circuit diagram illustrating a configuration of a semiconductor storage device 1 according to a fourth modification example of the embodiment. In this configuration, it is also possible to realize an effect similar to that of the embodiment and to further reduce a circuit area.

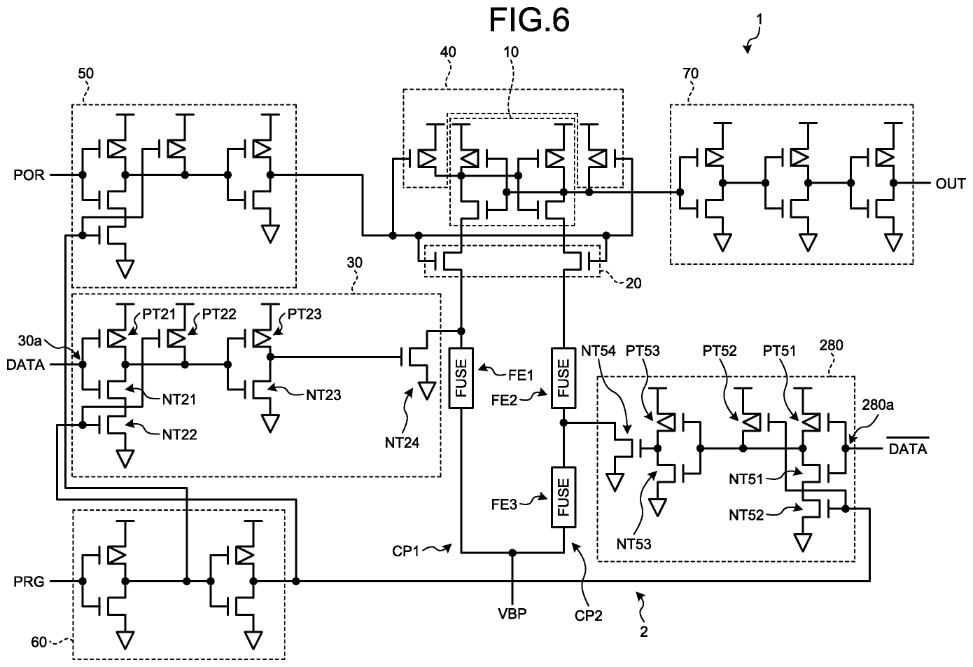

Also, a writing circuit that performs writing may be connected to a current path CP2 instead of a dummy writing circuit. For example, as illustrated in FIG. 6, a writing circuit 280 is connected to the current path CP2. FIG. 6 is a circuit diagram illustrating a configuration of a semiconductor storage device 1 according to a fifth modification example of the embodiment. The writing circuit 280 is connected to a node between a fuse element FE2 and a fuse element FE3. The writing circuit 280 includes an NMOS transistor NT51, a PMOS transistor PT51, an NMOS transistor NT52, a PMOS transistor PT52, an NMOS transistor NT53, a PMOS transistor PT53, and an NMOS transistor (writing transistor) NT54. The writing circuit 280 has a connection configuration similar to that of the writing circuit 30, and performs an operation similar to that of the writing circuit 30.

In this configuration, the writing circuit 30 receives data DATA in an input node 30a, and the writing circuit 280 receives data DATA in a corresponding input node 280a. Accordingly, when the writing circuit 30 writes bit information “1” into a fuse element FE1, the writing circuit 280 makes the fuse element FE3 hold bit information “0” without performing writing. Also, when the writing circuit 280 writes the bit information “1” into the fuse element FE3, the writing circuit 30 makes the fuse element FE1 hold the bit information “0” without performing writing. As a result, it is possible to make a memory circuit 2 hold the data DATA complementarily and to make the memory circuit 2 securely hold the bit information.

In this configuration, it is also possible not only to realize an effect similar to that of the embodiment but also to make capacity loads the same between a current path CP1 and a current path CP2. As a result, it is possible to increase a margin of a resistance value in a case of reversing a magnitude relationship of resistance values in the current paths CP1 and CP2 according to existence/non-existence of writing of bit information, that is, a bit information reading margin.

Also, in this configuration, when at least one of a latch circuit 10 and a connection circuit 20 is configured in such a manner that current driving capability with respect to the current path CP1 becomes adequately higher than current driving capability with respect to the current path CP2, it is possible to reverse a magnitude relationship of resistance values in the current paths CP1 and CP2 according to existence/non-existence of writing of bit information into the fuse element FE1 even when the number of fuse elements arranged in the current path CP2 is reduced.

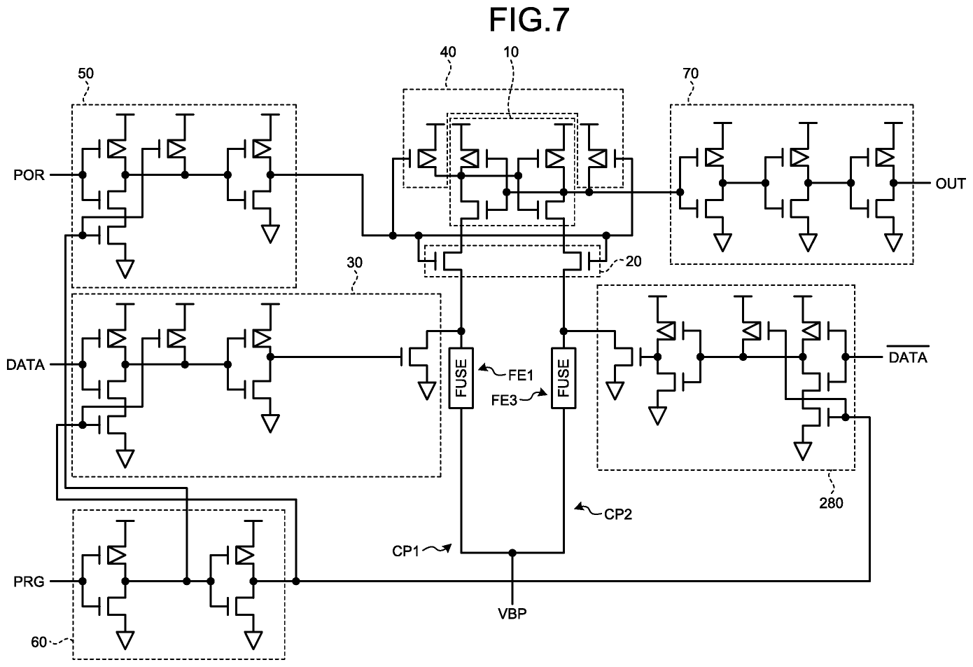

For example, as illustrated in FIG. 7, the number of fuse elements arranged in a current path CP2 may be made identical to the number of fuse elements arranged in a current path CP1 by omission of a fuse element FE2 (see FIG. 6) from the current path CP2. FIG. 7 is a circuit diagram illustrating a configuration of a semiconductor storage device 1 according to a sixth modification example of the embodiment. In this configuration, it is also possible to realize an effect similar to that of the embodiment and to further reduce a circuit area.

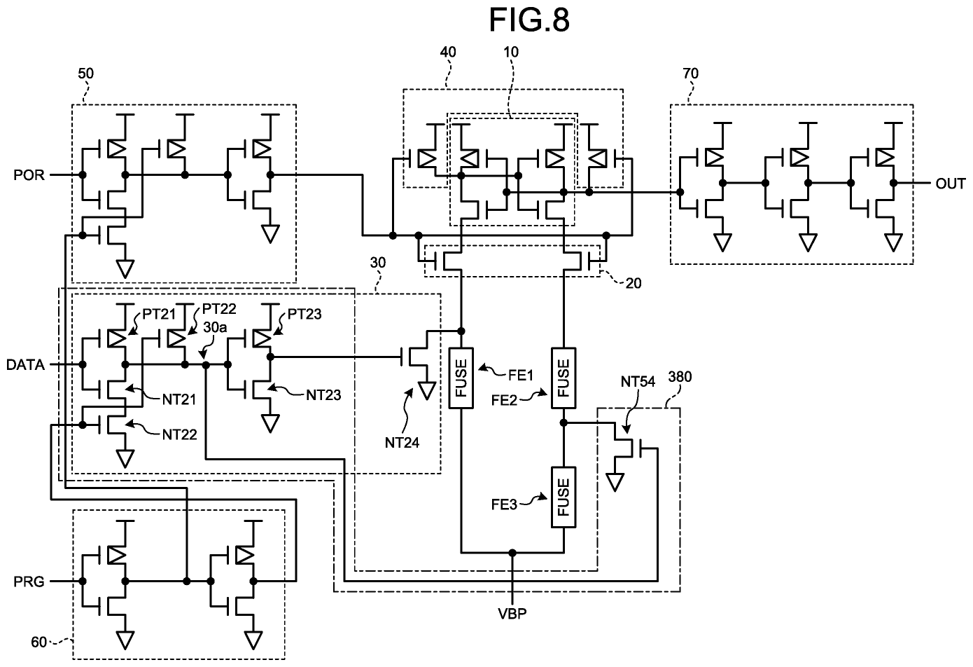

Also, it is possible to commonalize a partial configuration of a writing circuit 30 and a writing circuit 280 in a configuration illustrated in FIG. 6. For example, as illustrated in FIG. 8, a writing circuit 380 is configured by replacement of an NMOS transistor NT51, a PMOS transistor PT51, an NMOS transistor NT52, a PMOS transistor PT52, an NMOS transistor NT53, and a PMOS transistor PT53 respectively with an NMOS transistor NT21, a PMOS transistor PT21, an NMOS transistor NT22, a PMOS transistor PT22, an NMOS transistor NT23, and a PMOS transistor PT23 while a connection relationship in a writing circuit 280 is kept. FIG. 8 is a circuit diagram illustrating a configuration of a semiconductor storage device 1 according to a seventh modification example of the embodiment. Here, a gate of an NMOS transistor (writing transistor) NT54 is connected to an intermediate node 30a in a writing circuit 30. Accordingly, the writing circuit 380 illustrated in FIG. 8 can realize an operation similar to that of the writing circuit 280 illustrated in FIG. 6. In the configuration illustrated in FIG. 8, a circuit area can be reduced compared to a configuration illustrated in FIG. 6.

In this configuration, it is also possible not only to realize an effect similar to that of the embodiment but also to make capacity loads the same between a current path CP1 and a current path CP2. As a result, it is possible to increase a margin of a resistance value in a case of reversing a magnitude relationship of resistance values in the current paths CP1 and CP2 according to existence/non-existence of writing of bit information, that is, a bit information reading margin.

Also, in this configuration, when at least one of a latch circuit 10 and a connection circuit 20 is configured in such a manner that current driving capability with respect to the current path CP1 becomes adequately higher than current driving capability with respect to the current path CP2, it is possible to reverse a magnitude relationship of resistance values in the current paths CP1 and CP2 according to existence/non-existence of writing of bit information into the fuse element FE1 even when the number of fuse elements arranged in the current path CP2 is reduced.

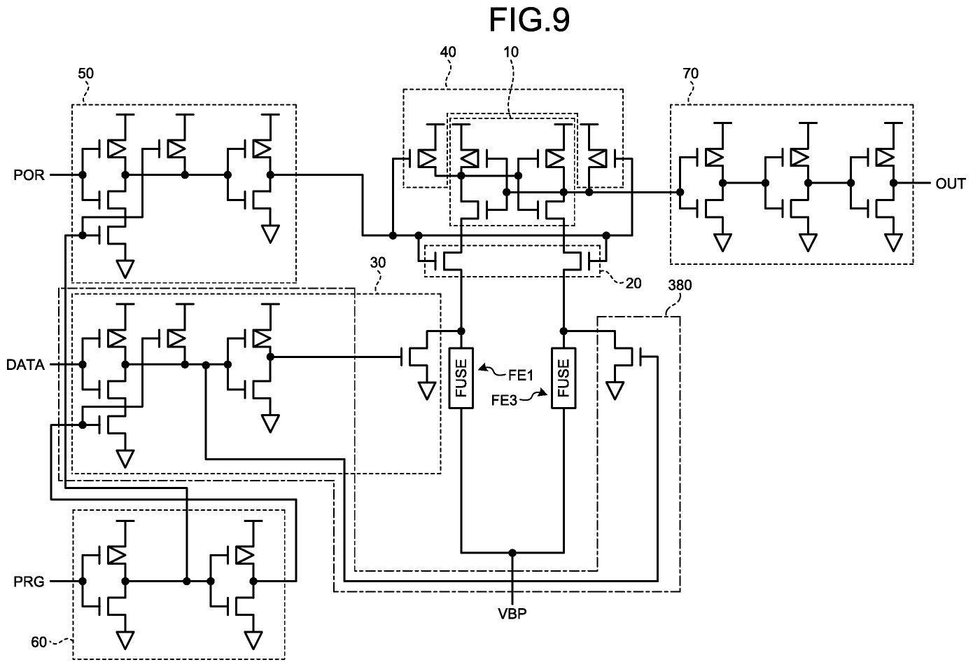

For example, as illustrated in FIG. 9, the number of fuse elements arranged in a current path CP2 may be made identical to the number of fuse elements arranged in a current path CP1 by omission of a fuse element FE2 (see FIG. 6) from the current path CP2. FIG. 9 is a circuit diagram illustrating a configuration of a semiconductor storage device 1 according to an eighth modification example of the embodiment. In this configuration, it is also possible to realize an effect similar to that of the embodiment and to further reduce a circuit area.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a latch circuit arranged across a first current path and a second current path;
a connection circuit arranged across the first current path and the second current path;
a first fuse element arranged in the first current path; and
a writing circuit electrically connected to one end of the first fuse element,
wherein at least one of the latch circuit and the connection circuit has higher current driving capability with respect to the first current path than current driving capability with respect to the second current path.

2. The semiconductor storage device according to claim 1, further comprising
a second fuse element arranged in the second current path.

3. The semiconductor storage device according to claim 2, further comprising
a third fuse element arranged between the second fuse element in the second current path and ground potential.

4. The semiconductor storage device according to claim 1, wherein
the latch circuit includes
a first NMOS transistor and a first PMOS transistor that are connected to each other in series in the first current path, gates thereof being connected to the second current path, and
a second NMOS transistor and a second PMOS transistor that are connected to each other in series in the second current path, gates thereof being connected to the first current path, and
wherein current driving capability of the first NMOS transistor is higher than current driving capability of the second NMOS transistor.

5. The semiconductor storage device according to claim 1, wherein
the latch circuit includes
a first NMOS transistor and a first PMOS transistor that are connected to each other in series in the first current path, gates thereof being connected to the second current path, and
a second NMOS transistor and a second PMOS transistor that are connected to each other in series in the second current path, gates thereof being connected to the first current path, and
wherein current driving capability of the first PMOS transistor is lower than current driving capability of the second PMOS transistor.

6. The semiconductor storage device according to claim 4, wherein
the connection circuit includes
a third NMOS transistor that is connected to the first NMOS transistor and the first PMOS transistor in series in the first current path and that receives a control signal at a gate, and
a fourth NMOS transistor that is connected to the second NMOS transistor and the second PMOS transistor in series in the second current path and that receives a control signal at a gate, and
wherein current driving capability of the third NMOS transistor is higher than current driving capability of the fourth NMOS transistor.

7. The semiconductor storage device according to claim 1, wherein
the connection circuit includes
a third NMOS transistor that is arranged in the first current path and that receives a control signal at a gate, and
a fourth NMOS transistor that is arranged in the second current path and that receives a control signal at a gate, and
wherein current driving capability of the third NMOS transistor is higher than current driving capability of the fourth NMOS transistor.

8. The semiconductor storage device according to claim 4, wherein
a dimension of the first NMOS transistor is larger than a dimension of the second NMOS transistor.

9. The semiconductor storage device according to claim 5, wherein
a dimension of the first PMOS transistor is smaller than a dimension of the second PMOS transistor.

10. The semiconductor storage device according to claim 6, wherein
a dimension of the third NMOS transistor is larger than a dimension of the fourth NMOS transistor.

11. The semiconductor storage device according to claim 7, wherein
a dimension of the third NMOS transistor is larger than a dimension of the fourth NMOS transistor.

12. The semiconductor storage device according to claim 4, wherein
a threshold voltage of the first NMOS transistor is lower than a threshold voltage of the second NMOS transistor.

13. The semiconductor storage device according to claim 5, wherein
a threshold voltage of the first PMOS transistor is higher than a threshold voltage of the second PMOS transistor.

14. The semiconductor storage device according to claim 6, wherein
a threshold voltage of the third NMOS transistor is lower than a threshold voltage of the fourth NMOS transistor.

15. The semiconductor storage device according to claim 7, wherein
a threshold voltage of the third NMOS transistor is lower than a threshold voltage of the fourth NMOS transistor.

16. The semiconductor storage device according to claim 2, further comprising
a second writing circuit electrically connected to one end of the second fuse element.

17. The semiconductor storage device according to claim 16, wherein
the second writing circuit is a dummy writing circuit.

18. The semiconductor storage device according to claim 16, wherein
the writing circuit writes bit information into the first fuse element according to first data, and
the second writing circuit writes bit information into the second fuse element according to second data logically inverted from the first data.

19. The semiconductor storage device according to claim 16, further comprising
a third fuse element arranged between the second fuse element in the second current path and the connection circuit.

20. The semiconductor storage device according to claim 16, wherein
a partial configuration of the writing circuit and the second writing circuit is commonalized.
